(19) United States
(12) Patent Application Publication
(10) Pub. No.: US 2012/0160168 A1
(43) Pub. Date: Jun. 28, 2012

(54) PLASMA GENERATION DEVICE WITH ELECTRON CYCLOTRON RESONANCE

(75) Inventors: Marc-Yves Delaunay, Meylan (FR); Denis Hitz, Grenoble (FR)

(73) Assignee: Commissariat a l'energie atomique et aux energies alternatives, Paris (FR)

(21) Appl. No.: 13/375,974

(22) PCT Filed: Jun. 4, 2010
(86) PCT No.: PCT/EP2010/057838

§ 371 Date: Mar. 12, 2012

(30) Foreign Application Priority Data
Jun. 5, 2009 (FR) 0953740

(51) Int. Cl. H05H 1/46; C01B 6/00; C23C 16/50; G21K 5/04

(52) U.S. Cl. 118/723 R; 315/111.71; 250/492.3; 422/162

(57) ABSTRACT

A plasma-generation device with electron cyclotron resonance, includes two adjacent sealed vacuum chambers configured to contain plasmas, an injector configured to inject a high-frequency wave into the chambers, a magnetic structure to generate a magnetic field in the chambers including a plurality of parallelepipedal permanent magnets and generating at least two plasmas according to the magnetic field lines, the module of the magnetic field having a magnetic mirror configuration with at least one electron cyclotron resonance area per plasma, the magnetic structure including at least one permanent magnet contributing to the formation of a plasma in each one of the chambers, such that the chambers share the same at least one permanent magnet on the common wall thereof.

The present invention relates to a device for generating a plurality of electron cyclotron resonance plasmas having a common magnetic structure.

To create an electron cyclotron resonance (ECR) plasma, it is necessary to generate magnetic fields which confine the plasma and which make it possible to satisfy the condition of resonance of the plasma electrons. These magnetic fields may be created by an electric current circulating in coils or by permanent magnets.

Permanent magnets have the advantage of having zero electrical consumption, but pose the drawback of not being able to generate short-range magnetic fields. For example, if a person skilled in the art decides to create a long and/or tall plasma (for example measuring a few metres) confined by permanent magnets, the ECR plasma will only be able to be a few centimetres thick. If a person skilled in the art also wants to produce a thick plasma (for example measuring a few tens of centimetres) he will have to use solenoids, which are high consumers of energy.

Such electron cyclotron resonance plasma generation devices are used for example for hydrogen production.

In fact, hydrogen (H₂) now appears to be a very interesting energy vector which is increasingly gaining in importance and could eventually advantageously substitute petrol and fossil fuels, of which the reserves will decrease rapidly in the coming decades. In view of this, it is necessary to develop effective hydrogen production methods.

A method for producing hydrogen by injecting water vapour into a plasma is described in particular in document US2004/0265137. This patent describes a method for obtaining hydrogen from the vapour dissociated in a plasma. In particular, the document mentions the use of electron cyclotron resonance (ECR) to produce said plasma. Compared to other known hydrogen production methods, the use of an ECR plasma machine provides a number of advantages:
continuous and stable operation;
no use of elevated temperatures;
no wear (very long service life caused by the absence of filament or electrodes);
no production of carbon or carbon compounds;
no use of chemical complexes;
low cost if the magnetic structure is formed of permanent magnets,

However, in spite of the above-mentioned advantages, such a plasma machine which breaks, by electronic impact, the bonds of the water molecule, has two major drawbacks: the range of the plasma, which does not reach far enough, makes it impossible to produce a large amount of hydrogen, and there is difficulty in separating the products formed by the dissociation of the water molecule.

On this basis, the object of the present invention is to provide an electron cyclotron resonance plasma generation device which enables effective dissociation of injected molecules, simple separation of formed products not necessarily requiring implementation of considerable magnetic fields, and which enables for example substantial production by volume of hydrogen by dissociation of water, whilst minimising the consumption of electrical energy.

To this end, the invention proposes an electron cyclotron resonance plasma generation device characterised in that it comprises:
at least two sealed adjacent chambers under vacuum for containing plasmas;
a high-frequency wave injector inside said at least two sealed chambers;
a magnetic structure for generating a magnetic field in said at least two adjacent chambers comprising a plurality of parallepipedal permanent magnets and generating at least two plasmas along the magnetic field lines, said module of said magnetic field having a magnetic mirror configuration, with at least one plasma electron cyclotron resonance zone for each plasma, said magnetic structure comprising at least one permanent magnet contributing to the formation of a plasma in each of said at least two chambers, such that said at least two chambers share the same at least one permanent magnet on their common wall,
   said magnetic mirror configuration is such that the module of said magnetic field has a substantially constant non-point minimum substantially equal to the magnetic field corresponding to the electron cyclotron resonance, extended at least in part along a first longitudinal axis of said at least two chambers and at least in part along a second axis perpendicular to said first longitudinal axis and parallel to the surface of said permanent magnets, such that said at least two chambers have a volume of electron cyclotron resonance plasma.

“Sealed chamber under vacuum” is understood to mean a chamber in which a working pressure less than or equal to 5·10⁻³ mbar prevails, said working pressure corresponding substantially to the partial pressure of the molecules injected into the chamber.

“Longitudinal axis of the chamber” is understood to mean the axis along which the plasma has its greatest dimension.

“Magnetic field substantially equal to the magnetic field corresponding to the electron cyclotron resonance” is understood to mean a magnetic field equal, give or take, to ±10% of the magnetic field corresponding to the electron cyclotron resonance.

“Substantially constant magnetic field” is understood to mean a magnetic field value which does not deviate by more than 10% of the value of the resonance magnetic field.

According to the invention, the magnetic structure is a structure of permanent magnets, of zero electrical consumption, generating in each chamber a volume of (ECR) plasma whilst minimising the number of permanent magnets used.

The magnetic structure generates a magnetic field of which the minimum value of the module of the magnetic field is extended, at least in part, over a large portion of the inner volume of the chambers.

The device according to the invention comprises a plurality of sealed chambers under vacuum, each for containing a volume of plasma, such that two successive chambers communicate at one of their ends and two adjacent chambers share at least the same common magnetic element on their common wall.

The two adjacent chambers preferably share a plurality of magnetic elements on their common wall.

In this way, it is possible to stack a plurality of plasma chambers of which the common magnetic structure makes it possible to generate a plurality of plasma volumes.

When the device according to the invention is used for hydrogen production, this production of hydrogen from water vapour is thus very effective, producing a large amount of hydrogen which consumes little energy whilst having a compact hydrogen production device.

The hydrogen production is based on the dissociation of water by the use of electron cyclotron resonance plasma. However, the efficacy of the device according to the invention can be increased by placing in parallel a plurality of chambers and by using common magnetic means which generate two adjacent plasmas, it being possible for the plasmas to be generated either in the same chamber or in separate chambers.

Thanks to the principle of the electron cyclotron resonance plasma, when passing from the proximity of the resonance zone, the electrons acquire energy. They will therefore be able to dissociate the injected molecules, for example water molecules, then ionise the dissociation products. Thanks to the electroneutrality of the plasma, these ions will follow the electrons along the magnetic field lines.

According to the invention, the mirror configuration of the magnetic field forms a magnetic field profile having a non-point minimum called a “flat field” minimum along the longitudinal axis of the chamber, of which the value of the module of the magnetic field is equal to the value of the resonance magnetic field, give or take ±10%. This value of the module of the minimum magnetic field, which is equal to or very close to the electron cyclotron resonance is extended at least in part along the longitudinal axis of the sealed chamber of the device, typically over a length greater than ten centimetres and possibly reaching a few metres, between the two maxima of the magnetic field.

According to the invention, the shape, positioning and dimensions of the magnetic structure make it possible to extend this minimum value of the module of the magnetic field, which is equal to or very close to the electron cyclotron resonance, at least in part along the second axis perpendicular to the longitudinal axis, and parallel to the surface of the permanent magnets, typically over a length which is greater than five centimetres so as to have in each sealed chamber an extended volume of hot plasma.

The magnetic structure must satisfy the condition of electron cyclotron resonance over volume. If we consider a microwave frequency of 2.45 GHz, the condition of resonance requires a magnetic field of Bᵣₑₛ=0.0875T. A person skilled in the art will use a magnetic structure calculation code so as to meet this condition of resonance uniformly for each plasma of each sealed chamber. The magnetic structure will be determined as a function of the hysteresis magnetic field and of the coercive magnetic field of each magnetic material, such as an alloy of samarium cobalt or an alloy of neodymium iron boron.

In this way, the electrons will be able to acquire a large amount of energy so as to effectively dissociate the water molecules and ionise the dissociation products. Moreover, during the production of hydrogen, the oxygen produced by the dissociation of the injected molecules could, for example, be trapped by selective cryogenic condensers along the length of the sealed chamber over a large length as well as over a large width.

It is noted that, although it uses an electromagnetic field, the device according to the invention does not use a method of thermal stirring of the water molecules, but in contrast breaks the atomic bonds by collisions with the plasma electrons.

The device according to the invention may also have one or more of the features below, considered individually or in any technically feasible combination:
said plurality of permanent magnets forms an open magnetic structure;
said permanent magnets have the same direction of magnetisation and/or are of different sizes;
said plurality of permanent magnets comprises at least two magnets defining the ends of each chamber and generating a mirror magnetic field, said at least two magnets being located on either side of at least one magnet generating a resonance zone;
said at least two sealed chambers communicate at one of their ends;
said high-frequency wave injector is a multi-guide wave injector coupled to a single high-frequency generator;
said high-frequency wave injector is a waveguide injector comprising a cone for distributing microwaves in said plurality of chambers, said injector being coupled to a single high-frequency generator;
the device comprises a multi-frequency high-frequency waves injector.

The invention also relates to a hydrogen production device having an electron cyclotron resonance plasma comprising:
a plasma generation device according to the invention;
a water vapour injector into said at least two chambers, the electrons of said plasmas dissociating, at least in part, the water molecules introduced in the vapour phase and ionising, at least in part, the dissociation products, said water vapour injector injecting said water vapour in such a way that it is directed along said longitudinal axis of said at least two chambers;
a hydrogen and oxygen separator;
a recovering device for recovering the hydrogen produced by the dissociation.

The hydrogen production device preferably comprises a recovering device for recovering undissociated water, said recovering device being formed by a condenser and/or being arranged substantially along the axis of injection of the water vapour.

The hydrogen production device preferably comprises at least one system for re-injecting the undissociated water in vapour phase provided by said recovering device for recovering undissociated water.

The hydrogen production device is such that said recovering device for recovering hydrogen produced by the dissociation comprise a pump for pumping the hydrogen in gaseous phase and/or at least one cryogenic condenser for freezing the hydrogen.

The hydrogen production device is such that said water vapour injector injects said water vapour in the form of a supersonic jet, said water vapour injector comprising a flat nozzle and a divertor, said divertor being used to shape said vapour jet so that it is directed along the longitudinal axis of said at least two chambers.

The hydrogen production device is such that said hydrogen and oxygen separator is formed by at least one selective cryogenic condenser for freezing the oxygen produced by the dissociation without freezing the hydrogen produced by the dissociation, said at least one selective cryogenic condenser freezing the oxygen along said volume of plasma generated in said at least two chambers.

The hydrogen production device is such that said at least one selective cryogenic condenser for freezing the oxygen forms the inner wall of said chamber and/or is situated at said magnetic field non-point minimum.

The hydrogen production device preferably comprises a second cryogenic condenser for freezing the oxygen produced by the dissociation, said condenser being located at the end of said at least two chambers between said magnetic mirror configuration and said hydrogen recovering device.

The hydrogen production device is such that said hydrogen and oxygen separator is formed by a hydrogen-permeable membrane, said permeable membrane separating the hydrogen produced by the dissociation along said volume of plasma generated in said at least two chambers.

The invention also relates to a device for producing thin layers, comprising:
a plasma generation device according to the invention;
a plasma component injector into said at least two chambers, the electrons of said plasmas dissociating, at least in part, the molecules of said introduced component and ionising, at least in part, the products of the dissociation, said plasma component injector injecting said component in such a way that it is directed along said longitudinal axis of said at least two chambers;
   said plasmas successively producing thin layers of product of the dissociation of said component so as to form a stack of thin layers on a substrate.

The device for producing thin layers preferably comprises a system for displacing said substrate by positioning said substrate successively in front of each plasma.

The device for producing thin layers is such that said component injected into each of said at least two chambers is different in nature so as to form a stack of thin layers of different natures on said substrate.

The invention also relates to an implantation device comprising:
a plasma generation device according to the invention;
a plasma component injector into said at least two chambers, the electrons of said plasmas dissociating the introduced molecules of said component and ionising the products of the dissociation, said plasma component injector injecting said component in such a way that it is directed along said longitudinal axis of said at least two chambers;
a high voltage of single polarisation for extracting the ions produced by each plasma and implanting them in the material;
   said plasmas each having a different state of charge distribution making it possible to successively implant ions of the same nature and/or having different charges.

Further features and advantages of the invention will become clearer from the non-limiting description given below by way of indication and with reference to the accompanying figures, in which:

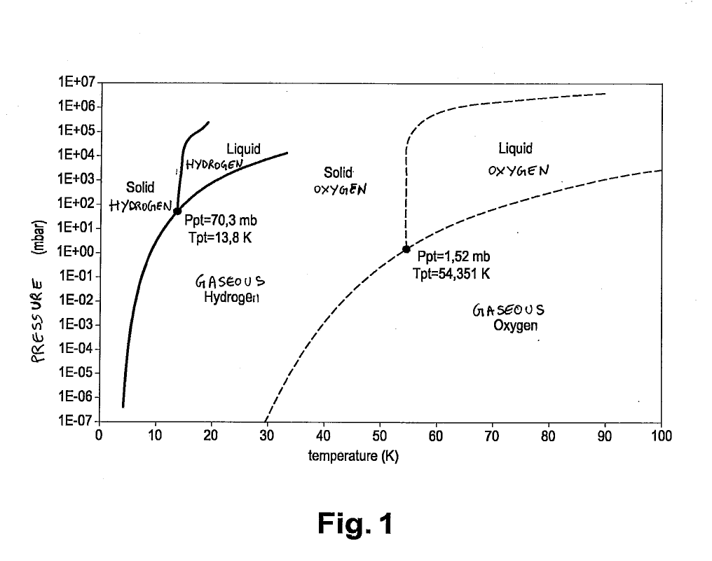

FIG. 1 is a view of phase diagrams of hydrogen and oxygen with the corresponding values at the triple point of each element;

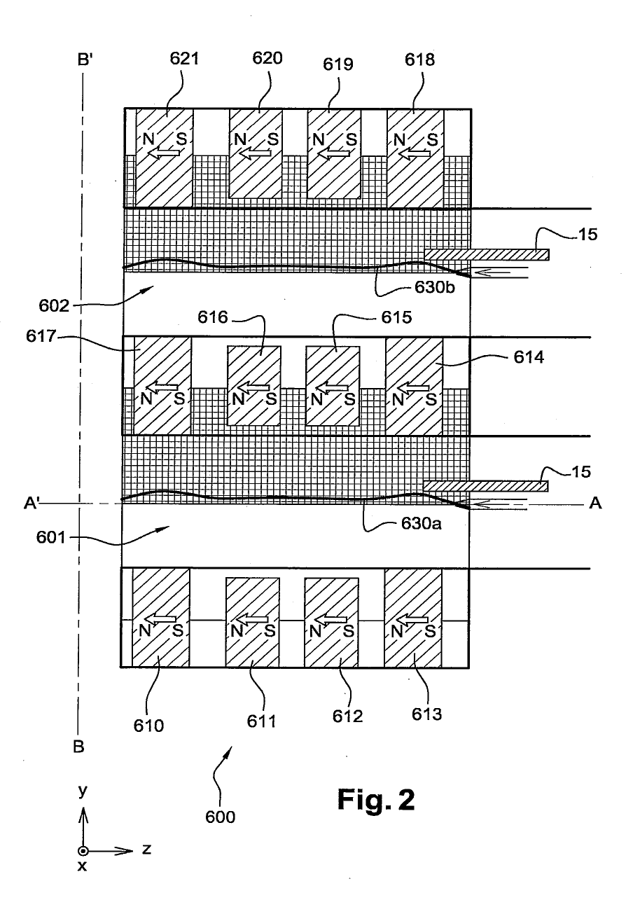

FIG. 2 is a plan view of a device for generating electron cyclotron resonance plasma according to the invention;

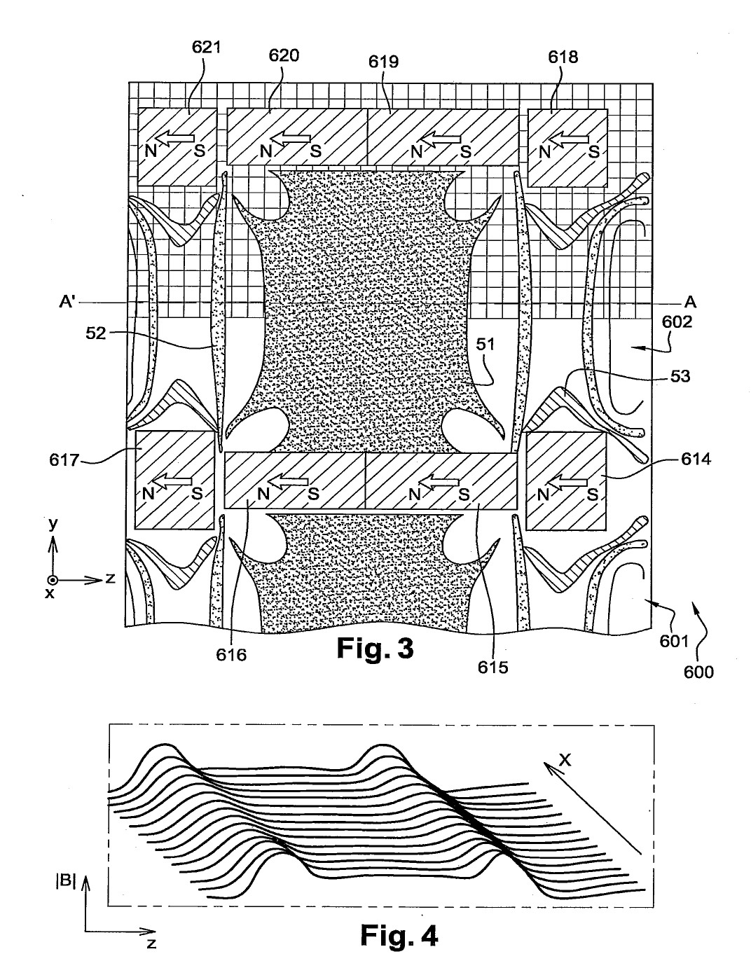

FIG. 3 is a plan view of an example of distribution of the magnetic field in a chamber of the device according to the invention;

FIG. 4 shows a distribution of the axial profiles of the module of the magnetic field in a chamber of the device according to the invention;

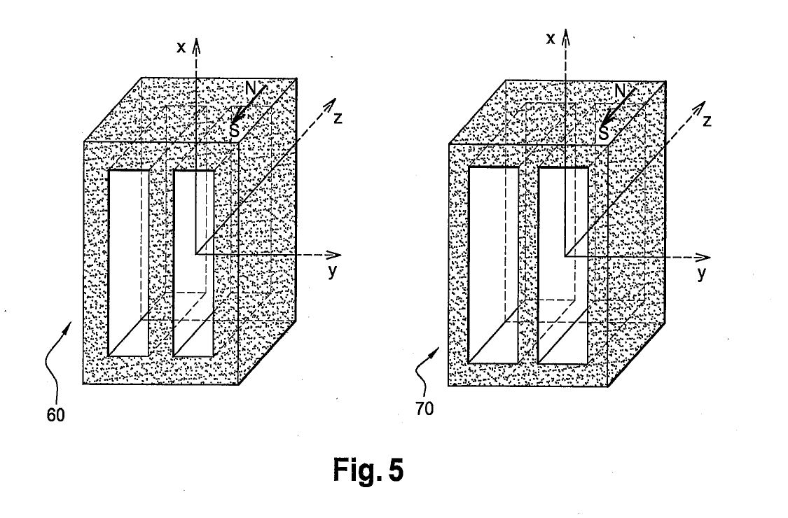

FIG. 5 shows a specific distribution of bar magnets of a device according to the invention;

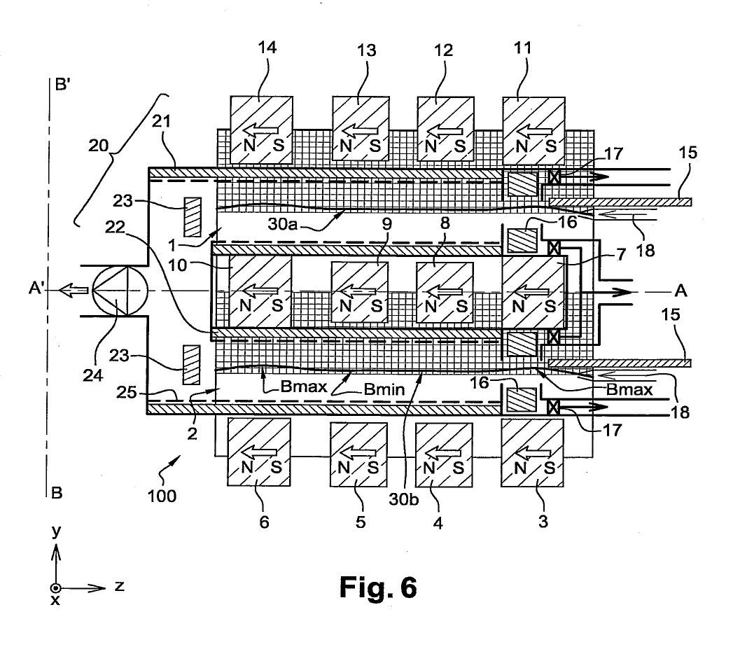

FIG. 6 is a plan view of a first embodiment of a hydrogen production device comprising the plasma generation device according to the invention;

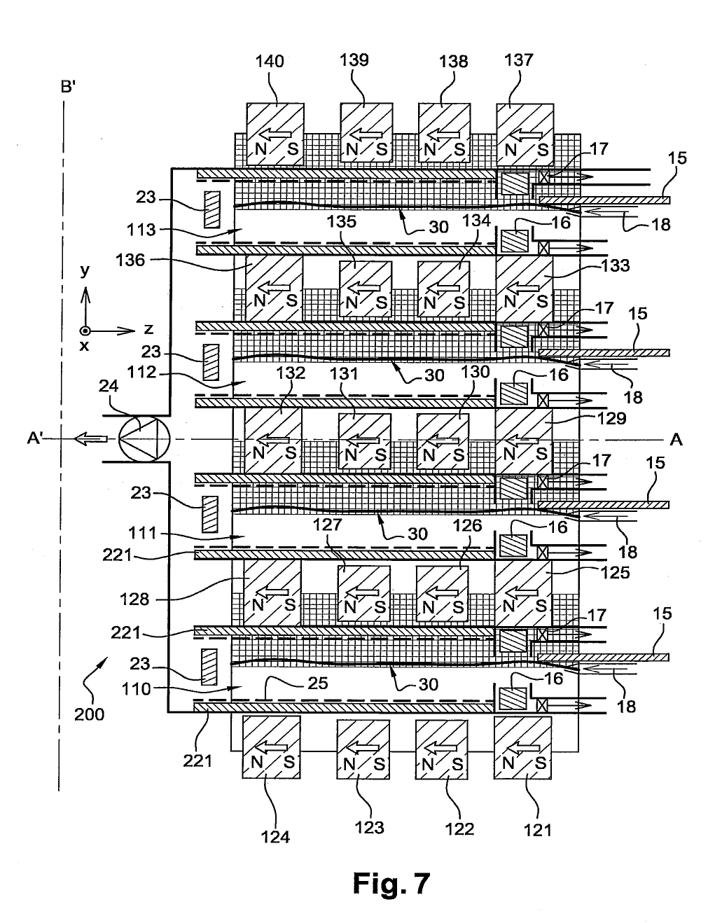

FIG. 7 is a plan view of a second embodiment of a hydrogen production device;

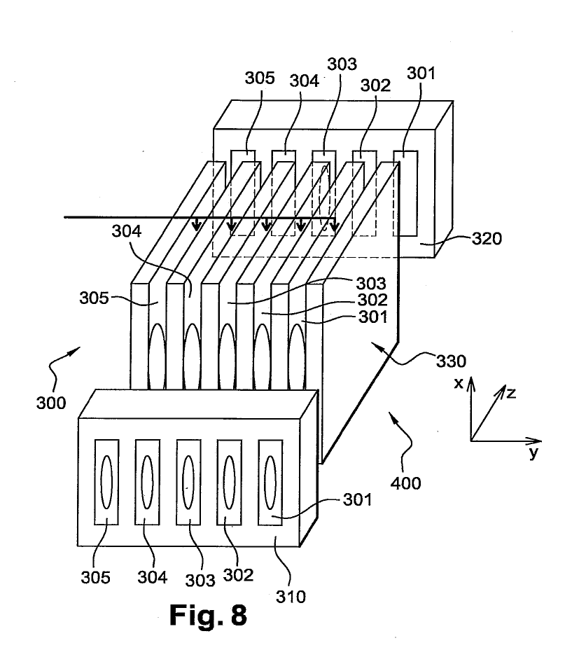

FIG. 8 shows a third embodiment of a hydrogen production device;

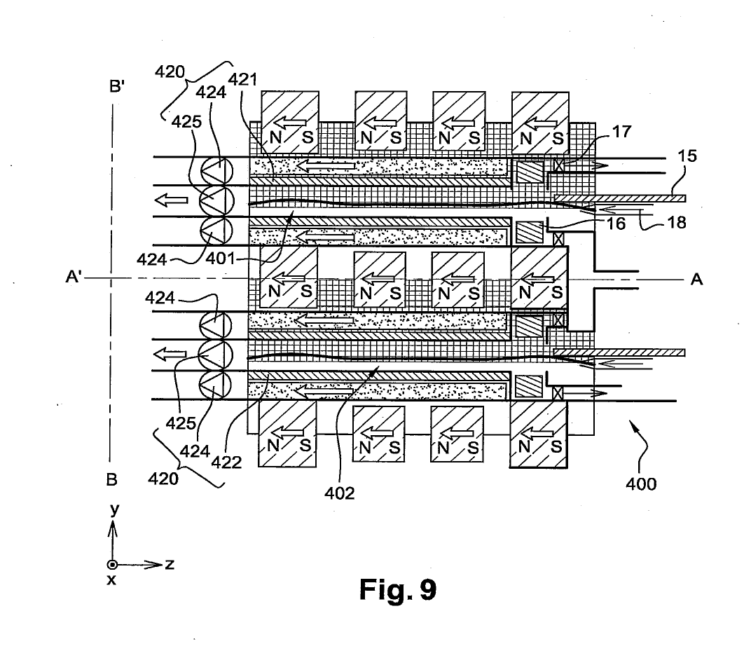

FIG. 9 is a plan view of a fourth embodiment of a hydrogen production device according to the invention;

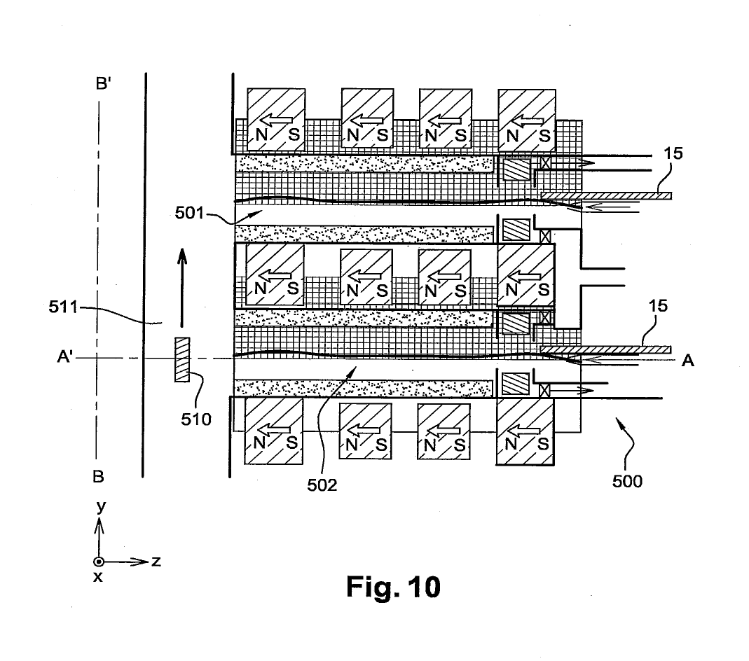

FIG. 10 is a plan view of a surface-treatment device comprising the plasma generation device according to the invention.

In all the figures, like elements are denoted by the same reference numerals.

FIG. 2 is a simplified view of a device 600 for generating electron cyclotron resonance plasma.

The device 600 comprises:
a first parallelepipedal sealed chamber 601, under vacuum, also referred to hereinafter as an enclosure;
a second parallelepipedal sealed chamber 602, under vacuum;
twelve permanent bar magnets 610, 611, 612, 613, 614, 615, 616, 617, 618, 619, 620, 621, of which eight bar magnets 610, 611, 612, 613, 618, 619, 620, 621 are placed outside the space formed by the chambers 601 and 602, and of which four bar magnets 614, 615, 616, 617 are placed between the first chamber 601 and the second chamber 602, the bars typically having a height between a few centimetres and a metre, and greater if necessary; the magnets 610, 613, 614, 617, 618, 621 are preferably identical and form the mirror magnetic fields, and the magnets 611, 612, 615, 616, 619, 620 are identical and form the resonance zones.
transmission medium 15 for propagating high-frequency waves of the low-frequency microwave type less than or substantially equal to 2.45 GHZ, formed by a waveguide or a coaxial cable equipped with a sealed high-frequency aperture within the chambers 601 and 602.

The chambers 601 and 602 of the device 600 are placed under vacuum, the vacuum being produced by ad hoc pumping means. So as to have minimal impurities in the chambers 601 and 602, a residual vacuum of at least 10⁻⁴ mbar is required. During operation of the device 600, the working pressure in the chambers 601 and 602 is typically less than or equal to 5·10⁻³ mbar, this pressure being linked to the partial pressure of the molecules injected into the chambers 601 and 602.

The eight permanent bar magnets 610, 611, 612, 613, 614, 615, 616, 617 of the magnetic structure have the same direction of magnetisation and surround the first chamber 601.

The shape and orientation of the permanent magnets 610, 611, 612, 613, 614, 615, 616, 617 are such that, inside the chamber 601, the magnets produce an axial magnetic field of which the configuration of the module corresponds to a configuration of the magnetic mirror type, of which the profile 630a has at least two maxima (Bₘₐₓ) at the abscissae located respectively in the zones of injection and extraction and a non-point minimum (Bₘᵢₙ) extended at least in part and preferably over a large portion along the chamber 601, along the longitudinal axis AA′, and is located between the two maxima (Bₘₐₓ).

The magnetic structure is also formed by the four permanent bar magnets 618, 619, 620, 621 having the same direction of magnetisation which, combined with the bar magnets 614, 615, 616, 617, surround the second chamber 602 so as to produce inside the chamber 602 a second axial magnetic field, of which the configuration of the module corresponds to a configuration of the magnetic mirror type of which the profile 630b has at least two maxima (Bₘₐₓ) at the abscissae located respectively in the zones of injection and extraction and a non-point minimum (Bₘᵢₙ) extended at least in part along the chamber 1, along the longitudinal axis AA', and is located between the two maxima (Bₘₐₓ).

The bar magnets 614, 615, 616, 617 of the magnetic structure are common to the two chambers 601 and 602 and are dimensioned to produce an equivalent magnetic field both inside the chamber 601 and inside the chamber 602. The magnetic fields thus have the same profile 630a and 630b inside the chambers 601 and 602.

The bar magnets 614, 615, 616, 617 are placed under vacuum in welded casings which are made of a non-magnetic metal material and are vacuum sealed, thus making it possible to overcome problems linked to the degassing of magnets.

The maxima (Bₘₐₓ) of the profiles 630 have a value greater than the value of the resonance magnetic field (Bᵣₑₛ) for which the electron cyclotron resonance is obtained. The minimum (Bₘᵢₙ) is a minimum called a flat field, of which the value is equal to or slightly less than the value for which the electron cyclotron resonance is obtained, and is extended over a large length of the device 600.

The magnetic structure as shown in FIG. 2 also makes it possible to extend the mirror configuration of the profile of the module of the magnetic field along the transverse axis BB′ inside the chambers 601 and 602.

The magnetic structure described above thus makes it possible to obtain, inside the chambers 601 and 602, an extended volume of the hot plasma.

The mirror configuration of the magnetic field is a configuration called minimum-B: the plasma electrons are confined in a magnetic well. The greater and more extended the length of the minimum-B, which is less than or equal to the value of the resonance magnetic field, the more the plasma volume will contain rapid electrons leading to improved dissociation of the injected molecules.

Thanks to the principle of electron cyclotron resonance, when passing from the resonance zone the electrons will acquire energy. They will therefore be able to dissociate the injected molecules, then ionise the dissociation products in part. The electrons follow the magnetic field lines thanks to Laplace's law; and, thanks to the electroneutrality of the plasma, these ions will follow the electrons along the magnetic field lines.

The microwaves injected into the plasma tend to propagate through the plasma as far as the resonance zone. In fact, the transfer of energy of the injected microwave power to the electrons of the plasma is produced in a magnetic field location (Bᵣₑₛ) so that the condition of electron cyclotron resonance is established, that is to say there is equality between the pulse of the high-frequency wave ω_{HF} and the cyclotron pulse of the electron:

ω_{HF}=ω_{ce}=qₑBᵣₑₛ/mₑ

in which qₑ is the charge of the electron (Cb);
Bᵣₑₛ is the magnetic field corresponding to the resonance (T);
mₑ is the mass of the electron.

A microwave generator (not shown) is placed outside the chambers 601 and 602 of the device 600; this generator injects high-frequency waves into the chambers 601 and 602 via the transmission medium 15. The frequency range of the microwaves may range from one GHz to about 100 GHz, the most common generator being the 2.45 GHz magnetron used commonly for domestic microwave ovens. For a frequency of 2.45 GHz, there is a resonance magnetic field Bᵣₑₛ=0.0875 T. However, for miniature devices (for on-board systems for example), it is also possible to use power transistors. In fact, there are now field-effect transistors which are capable of supplying approximately 60 W at 14.5 GHz.

Advantageously, the aperture for inlet of high-frequency waves is placed in a strong magnetic field zone, for example at the first maximum (Bₘₐₓ) of the profiles 630 of the module of the magnetic field, in such a way that the plasma volume diffuses towards the chambers 601 and 602 and not towards the inlet aperture so as to avoid any bombardment of this aperture by the plasma, thus ensuring a significant service life. It is also possible to use plasmas called “overdense” plasmas, where the plasma frequency is greater than the microwave frequency. The use of overdense plasmas advantageously makes it possible to increase the electronic density and thus increase the efficacy of the system.

Thanks to the magnetic structure and the flat minimum-B magnetic configuration along the longitudinal axis AA′, the chambers 601 and 602 have a plasma volume extending over a large portion inside each chamber with a significant density at the outlet of the jet of molecules to be dissociated and with a pressure gradient along each chamber.

FIG. 3 is a plan view of an example of distribution of isovalues of the module of the module of the magnetic field present in the plasma chambers 601 and 602 of the device 600 according to the invention.

FIG. 3 makes it possible to see more clearly the distribution of the value of the magnetic field inside the plasma chambers and in particular inside the chamber 602 along the plane of section yz.

Similarly to the description above, the chamber 602 is surrounded by a magnetic structure comprising permanent bar magnets 614, 615, 616, 617, 618, 619, 620, 621 all having the same direction of magnetisation.

The specific positioning and dimension of the bar magnets 614, 615, 616, 617, 618, 619, 620, 621 of the magnetic structure make it possible to produce, inside the chamber 602, a magnetic field of which the module has a mirror configuration about the axis AA′ and of which the value of the module is extended over a large portion of the width of the chamber 602, along the axis y.

The magnetic field within the chamber 602 thus has a minimum value (Bₘᵢₙ) equal to or very slightly less than the value of the resonance magnetic field (Bᵣₑₛ), which is very extended in the central portion of the chamber 602.

In particular, FIG. 3 shows the extent of the minimum value (Bₘᵢₙ) close to the value of the resonance magnetic field via the curve of the isovalue 51, the isovalue 51 also indicating the extent of the plasma sheet present in the chamber 602. Clearly, the plasma sheet comprises a third dimension corresponding to the height of the chamber 602 along the x axis.

FIG. 3 also shows curves of isovalues 52 and 53 corresponding substantially to the values of the module of the magnetic field close to the maxima (Bₘₐₓ) and of which the values are respectively 0.2T and 0.3T.

Thus, for any axis parallel to the axis AA′ and whatever the position along the y axis, the module of the magnetic field inside the chamber 602 has a profile with a mirror configuration comprising a flat non-point minimum-B extended along the chamber 602 and located between two maxima (Bₘₐₓ). FIG. 4 specifically shows the distribution of the profile of the module of the axial magnetic field in a chamber, of the device 600, for plasma at different heights.

FIG. 5 shows an embodiment of the permanent bar magnets described above in FIGS. 2 and 3.

In accordance with the specific embodiment of the device according to the invention described above, the bar magnets 610, 611, 612, 613, 614, 615, 616, 617, 618, 619, 620, 621 surrounding the chambers 602, 601 are formed by two types of rectangular magnet frames 60 and 70. The bar magnets 610, 613, 614, 617, 618, 621 shown in FIG. 1 are thus formed by the rectangular magnet frame 60, and the bar magnets 611, 612, 615, 616, 619, 620 illustrated in FIG. 1 are formed by the rectangular magnet frame 70.

Thus, for a frequency of 2.45 GHz, the magnet frame 60 typically has, along the xy plane, a rectangular section measuring 15.8 cm wide along the y axis and 26 cm long along the x axis and is hollowed at its centre by a rectangular section 6 cm wide and 16 cm long (this is one embodiment but of course there may be other combinations at a given frequency).

For the frequency of 2.45 GHz, the magnet frame 70 typically has, along the xy plane, a rectangular section measuring 15.8 cm wide along the y axis and 26 cm long along the x axis and is hollowed at its centre by a rectangular section 9 cm wide and 19 cm long (this is one embodiment but of course there may be other combinations at a given frequency).

The height along the z axis is defined by a person skilled in that art as a function of the space available and his needs. In fact, it may range from a few centimetres to several metres.

FIG. 5 thus specifically shows permanent magnet dimensions which make it possible to basically obtain a plasma volume measuring some cm³ at the frequency of 2.45 GHz.

However, the dimensions of these magnets 60, 70 are not limiting; it is also possible to use bar magnets having dimensions ranging from a few tens of centimetres to several metres if it is desired to obtain a greater production of dissociation products, for example a greater production of hydrogen.

FIG. 6 is a simplified view of a hydrogen production device 100 comprising a device 600 for generating electron cyclotron resonance plasma according to the invention, as described and illustrated in FIGS. 2, 3, 4 and 5.

The hydrogen production device 100 comprises, unless otherwise indicated, all the features of a plasma generation device 600 described above.

To this end, the device 100 comprises:
a first parallelepipedal sealed chamber 1, under vacuum (also referred to hereinafter as an enclosure);
a second parallelepipedal sealed chamber 2, under vacuum;
twelve permanent bar magnets 3, 4, 5, 6, 7, 8, 9, 10, 11, 12, 13, 14, of which eight bar magnets 3, 4, 5, 6, 11, 12, 13, 14 are placed outside the space formed by the chambers 1 and 2, and of which four bar magnets 7, 8, 9, 10 are placed between the first chamber 1 and the second chamber 2, the bars typically having a height between a few centimetres and a metre, and greater if necessary; the magnets 3, 6, 7, 10, 11, 14 are preferably identical and form the mirror magnetic fields, and the magnets 4, 5, 8, 9, 12, 13 are identical and form the resonance zones;
a high-frequency waves transmission medium 15 of the low-frequency microwave type less than or substantially equal to 2.45 GHZ, formed by a waveguide or a coaxial cable equipped with a sealed high-frequency aperture within the chambers 1 and 2;
a water vapour injector 18 into each chamber 1, 2 formed of an enclosure in which the water vapour resides, each enclosure being connected to a sealed chamber 1, 2 via a nozzle so as to create a supersonic jet of water vapour. The jets of water vapour are shaped using divertors formed of pipes in which a liquid circulates of which the temperature approaches 5° C. The water vapour which comes into contact with the divertors is immediately condensed and runs along the divertors. The vapour jets are thus limited in their radial dimension and are oriented along the longitudinal axis AA′ of the device 100; cryogenic condensers 16 for trapping undissociated water vapour so as to have a high level of directivity of the vapour jet;
pumps 17 for recycling undissociated water in vapour or liquid phase;
a system for separating dissociated hydrogen-oxygen products 20 formed by a plurality of membranes or a system for cryogenic entrapment of the oxygen.

In accordance with a first embodiment of such a hydrogen production device, the hydrogen-oxygen separation system 20 is a system for cryogenic separation of the dissociation products, formed by:
a first cryogenic condenser 21 for trapping oxygen, forming the outer lateral wall of the first chamber 1 and of the second chamber 2;
a second cryogenic condenser 22 for trapping oxygen, forming the inner lateral wall of the first chamber 1 and of the second chamber 2;
cryogenic condensers 23 for trapping the oxygen, located perpendicular to the axis AA′ of the device 100;
a pump 24 making it possible to recover hydrogen in gaseous form.

The chambers 1 and 2 of the device 100 are placed under vacuum, the vacuum being produced by ad hoc pumping means. So as to have minimal impurities in the chambers 1 and 2, a residual vacuum of at least 10⁻⁴ mbar is required. During operation of the device 100, the working pressure in the chambers 1 and 2 is typically less than or equal to 5·10⁻³ mbar, said pressure being linked to the partial pressure of water vapour injected into the chambers 1 and 2.

The magnetic structure is formed in particular by the eight permanent bar magnets 7, 8, 9, 10, 11, 12, 13, 14 having the same direction of magnetisation, the eight bar magnets 7, 8, 9, 10, 11, 12, 13, 14 surrounding the first chamber 1.

The orientation of the permanent magnets 7, 8, 9, 10, 11, 12, 13, 14 is such that, inside the chamber 1, the magnets produce an axial magnetic field of which the configuration of the module corresponds to a configuration of the magnetic mirror type, of which the profile 30a has at least two maxima (Bₘₐₓ) at the abscissae located respectively in the zones of injection and extraction, and a non-point minimum (Bₘᵢₙ) extended at least in part and preferably over a large portion along the chamber 1, along the longitudinal axis AA′, and is located between the two maxima (Bₘₐₓ).

The magnetic structure is also formed by four permanent bar magnets 3, 4, 5, 6 having the same direction of magnetisation which, combined with the bar magnets 7, 8, 9, 10, surround the second chamber 2 so as to produce inside the chamber 2 a second axial magnetic field, of which the configuration of the module corresponds to a configuration of the magnetic mirror type of which the profile 30b has at least two maxima (Bₘₐₓ) at the abscissae located respectively in the zones of injection and extraction, and a non-point minimum (Bₘᵢₙ) extended at least in part along the chamber 1, along the longitudinal axis AA′, and is located between the two maxima (Bₘₐₓ).

The bar magnets 7, 8, 9, 10 of the magnetic structure are common to the two chambers 1 and 2 and are dimensioned to produce a magnetic field equivalent both to the inside of the chamber 1 and to the inside of the chamber 2. The magnetic fields thus have the same profile 30 inside the chambers 1 and 2; the magnetic profile denoted by 30 being equivalent to the profiles 30a and 30b illustrated in FIG. 2, only the profile 30 will be referred to hereinafter for each of the chambers.

The bar magnets 7, 8, 9, 10 are placed under vacuum in welded casings which are made of a non-magnetic metal material and are vacuum sealed, thus making it possible to overcome problems linked to the degassing of magnets.

The maxima (Bₘₐₓ) of the profiles 30 have a value greater than the value of the resonance magnetic field (Bᵣₑₛ) for which the electron cyclotron resonance is obtained. The minimum (Bₘᵢₙ) is a minimum called a flat field minimum, of which the value is equal to or slightly less than the value for which the electron cyclotron resonance is obtained, and is extended over a large length of the device 100.

The maximum values (Bₘₐₓ) of the magnetic field are preferably quite high, approximately from 0.15T to 0.3T, so as to limit axial leaks of the plasma.

The minimum value (Bₘᵢₙ) is a value equal to or less than the value of the resonance magnetic field (Bᵣₑₛ) by approximately 90% of (Bres), that is to say approximately 0.08T for a frequency of 2.45 GHz. This value of the magnetic field equal to or slightly less than the electron cyclotron resonance is extended over a large portion of the length of the device along the longitudinal axis AA′, approximately 25 cm. The electrons can thus acquire a large amount of energy so as to effectively dissociate the water molecules over the entire length of the device 100.

The magnetic structure as shown in FIG. 3 makes it possible to extend the mirror configuration of the profile of the module of the magnetic field along the transverse axis BB′ within the chambers 1 and 2.

The magnetic structure described above makes it possible to obtain, within the chambers 1 and 2, an extended volume of hot plasma.

The mirror configuration of the magnetic field is a configuration called minimum-B: the plasma electrons are confined in a magnetic well. The greater and more extended the length of the minimum-B, which is less than or equal to the value of the resonance magnetic field, the more the plasma volume will contain rapid electrons leading to improved dissociation of the water vapour into oxygen and hydrogen.

In the hydrogen production device 100, the water vapour injector 18 and the chambers 1 and 2 are preferably placed close to the microwave transmission medium 15 (however, another location may also be selected for reasons of convenience). The water is introduced into the chambers 1, 2 in the form of a supersonic jet of vapour with the objective of obtaining a high level of directivity of water vapour so as to direct the water vapour directly into the volume of hot plasma towards the resonance zone of the chambers 1 and 2. This jet is ejected from a nozzle acting as an orifice in an enclosure in which the water vapour is located. Divertors are placed at the outlet of the nozzle so as to define the angular opening of the jet. These divertors are formed by pipes in which a liquid circulates, of which the temperature approaches 5° C. (a lower temperature would lead to solidification of the water over the divertors). The water vapour which comes into contact with the divertors is immediately condensed and runs along the divertors.

So as to further improve this directivity by reducing the size of the vapour jet, the cryogenic condensers 16 formed for example by cryogenic rings are placed at the first maxima (Bₘₐₓ) of the magnetic fields, of which the profiles 30, 30a, 30b represent the modules of the magnetic fields along the chambers. The cryogenic condensers 16, of which the temperature approaches 200 K, are used as diaphragms with the aim of trapping, by cryocondensation, the water vapour located in the external portion of the vapour jet. The condensers 16 also prevent saturation with undissociated water of the main cryogenic condensers 21 and 22, which are required for dissociation of ionised elements. If the cryogenic condensers 16 are saturated with water, a device (not shown) makes it possible to isolate the condensers 16 with the aim of regenerating them. For this, the device re-heats the cold walls of the condensers 16 so as to recover the water from the cold walls in liquid or gaseous form to be re-injected into the device 100 by the recycling pumps 17.

The cryogenic condensers 16 may also be replaced by liquid condensers comprising a vertical tubing in which a pressure gradient (from 10⁻³ mbar to 10² mbar or 1 bar) is established. The water, which passes from the vapour form into the liquid form, thus runs along the vertical tubing by gravity and is advantageously recycled via the recycling pump 17. However, if the recycling tubing is short, the pressure gradient in the tubing may remain low, and the water may be re-injected into the device 100 directly in vapour phase.

Thanks to the magnetic structure and the flat minimum-B magnetic configuration along the longitudinal axis AA′, the chambers 1 and 2 have a plasma volume extending over a large portion inside each chamber, with a significant density at the outlet of the vapour jet and a pressure gradient along each chamber.

The device 100 does not radially confine the plasma owing to the radial inhomogeneity of the magnetic field. In this case, the ionised particles forming the plasma tend to experience a radial drift, which is a known phenomenon in plasma physics.

The cryogenic condensers 21, 22, 23 are cold wall condensers, called cryo-panel or cryogenic panel condensers. The condenser 21 is advantageously placed over the inner walls of the outer surface of the chambers 1 and 2, and the condenser 22 is advantageously placed over the inner walls of the inner surface of the two chambers so as to condense the desired ionised particles. The cold walls of the condensers 21 and 22 have a temperature approaching, for example, 20 to 30 K so as to condense all the elements present in the plasma chambers except for hydrogen, which remains in gaseous form at this temperature at the working pressure of 0.1 Pa.

In fact, according to the phase diagrams illustrated in FIG. 1, at the operating pressure of the chambers 1 and 2, that is to say at least 5·10⁻³ mbar, and at a temperature between 6K and 40K (preferably between 5K and 30K), it is possible to cryocondense the oxygen while the hydrogen remains in gaseous form.

Thus, by using one or more cryogenic condensers 21, 22 forming the walls of the plasma chambers, cooled to a temperature such that the two elements, hydrogen and oxygen, constituting the plasma are in different phases (gaseous hydrogen and solid oxygen), the oxygen may be trapped in solid form without trapping the hydrogen, this being recovered by other means. The temperature of the condenser depends on the partial hydrogen pressures from the initial density of the plasma, which is itself a function of the microwave frequency injected. The oxygen being trapped, recovering device for recovering the hydrogen are then used, such as a conventional pump (a turbomolecular pump, for example) to pump the hydrogen. It is also possible to advantageously use the fact that the ionised particles follow, by plasma electroneutrality, the electrons which are guided by the magnetic field lines.

In fact, if the cryogenic oxygen condensers 21, 22, 23 are placed in the magnetic field lines, the cryogenic hydrogen condensers may then advantageously be placed outside the magnetic field lines.

It will be noted that the different components produced by the dissociation of water are basically H₂, O₂, OH, H, O, O⁺, H⁺, H₂⁺, O₂⁺, OH⁻. All the ionised elements neutralise before touching a wall (either a cold wall of a cryo-panel condenser or another wall), whilst the neutral elements recombine to form stable elements: H₂, O₂, H₂O.

The cryogenic condensers 23 are advantageously placed in the axis of vapour jets outside plasma volumes before the hydrogen pumping system 24, so as to condense the ionised particles of oxygen as well as the undissociated water vapour. Since the oxygen produced by the dissociation of water is trapped over the entire length of the device 100, it is thus suffice to pump the hydrogen axially at the other end of the device 100 and the send it into a compressor (not shown).

A high-frequency (HF) screen 25 is placed in front of the cryo-panels 21, 22 so as to protect the cryo-panels and to avoid heating thereof by the microwaves, the mesh of the HF screen 25 being determined as a function of the wavelength of the microwaves.

It will be noted that, in accordance with the grid shown in FIG. 6, one square on the abscissa basically corresponds to one centimetre. The dimensions of each magnet have been calculated so as to obtain, in the plasma chamber, a long and wide resonance zone in which the electrons take on sufficient energy to dissociate the water molecules and ionise, at least in part, the dissociation products.

The best rate of dissociation of water being obtained for pressures below 5·10⁻³ mbar, this value is considered to be a maximum pressure in the chambers 1 and 2, all the more so since the electrons would no longer be guided magnetically if this pressure were increased above 5·10⁻³ mbar.

It is also possible to use a source for injection of multi-frequency microwaves of which the bandwidth of each frequency forms a wide frequency band leading to the formation of a large resonance zone; the width of the resonance zone corresponding substantially to the bandwidth of the microwave source.

FIG. 7 is a variant of the device illustrated in FIG. 6 (the common means between the devices 100 and 200 bearing the same reference numerals and performing the same functions). The device 200 according to this second embodiment differs from the device 100 of FIG. 6 in that it comprises four plasma chambers 110, 111, 112, 113, 114, each comprising a plasma volume; each of the chambers 110, 111, 112, 113, 114 having the same features detailed above with reference to FIG. 6.

In this variant of the device, the magnetic structure is formed in particular by twenty permanent bar magnets numbered from 121 to 140 and having the same direction of magnetisation.

The bar magnets 121 to 140 are arranged in such a way that each chamber 110, 111, 112, 113, 114 is surrounded by eight permanent bar magnets, of which twelve bar magnets 125 to 136 are used commonly by two chambers so as to produce a magnetic field in each of the chambers which they surround. The bar magnets 125 to 136 are placed under vacuum in welded casings which are made of a non-magnetic metal material and are vacuum sealed, thus making it possible to overcome problems linked to the degassing of magnets.

The orientation of the permanent magnets 121 to 140 is such that, inside the chambers 110, 111, 112, 113, 114, the magnets produce an axial magnetic field of which the configuration of the module corresponds to a configuration of the magnetic mirror type, of which the profiles 30 have at least two maxima (Bₘₐₓ) at the abscissae located respectively in the zones of injection and extraction, and a non-point minimum (Bₘᵢₙ) extended at least in part and preferably over a large portion along the chambers 110, 111, 112, 113, 114 along the Z axis corresponding to the longitudinal axis of the device; the minimum (Bmin) being located between the two maxima (Bₘₐₓ).

In accordance with a specific embodiment of the invention, the bar magnets 121, 124, 125, 128, 129, 132, 133, 136, 137 and 140 have the same dimensions, this detail also being applicable to the bar magnets 122, 123, 126, 127, 130, 131, 134, 135, 138 and 139.

It will be noted that the device 200 comprises, in each chamber 110, 111, 112, 113, 114, a water vapour injector 18 and a high-frequency waves of the microwave type transmission medium 15.

In this second embodiment, the hydrogen/oxygen separation system is formed by:
cryogenic condensers 221 for trapping the oxygen, forming the outer lateral walls of each chamber 110, 111, 112, 113, 114;
cryogenic condensers 23 for trapping the oxygen, located perpendicular to the axis AA′ of the device 200;
a pump 24 making it possible to recover the hydrogen in gaseous form.

By contrast, the device 200 according to the invention only comprises one pump 24 which is common to all the chambers 110, 111, 112, 113, 114 for the recovery of hydrogen in gaseous form.

FIG. 8 is a variant of the devices 100, 200 illustrated in FIGS. 6 and 7. The device 300 according to this third embodiment differs from the device 100 of FIG. 6 and from the device 200 of FIG. 7 in that it comprises five plasma chambers 301, 302, 303, 304, 305, in particular each comprising a plasma volume. Each of the chambers has the same structural features detailed above with reference to FIGS. 6 and 7.

FIG. 8 more specifically shows a simplified and compact embodiment of the magnetic structure 400 of a device 300 according to the invention.

In this embodiment the magnetic structure 400 is formed of three permanent magnet blocks 310, 320, 330 aligned with the z axis corresponding to the longitudinal axis of the plasma chambers 301, 302, 303, 304, 305.

The two magnet blocks 310 and 320, located at the ends of the device 300, are magnet blocks said to be “closed” magnet blocks, whereas the central magnet block 330 is said to be “open” since it has openings in the upper part and in the lower part so as to facilitate the insertion of the cryo-panels for trapping oxygen as defined with reference to FIG. 6, or of any other element necessary for ordinary operation of the device. In this embodiment, the magnet blocks 310 and 320 are solid blocks typically having a length of 580 cm (along x), a width of 660 cm (along y) and a depth of 50 cm (along z). They also have five recesses each corresponding to one of the plasma chambers 301, 302, 303, 304, 305. These recesses typically have a length of 320 cm (along x) and a width of 70 cm (along y).

The magnet blocks 310 and 320 typically represent a portion of the magnetic structure 400 of the device 300 making it possible to surround each chamber 301, 302, 303, 304, 305, the magnet blocks 310 and 320 representing the bar magnets of each chamber located at the maxima Bₘₐₓ of the profiles of the module of the magnetic field present in each chamber 301, 302, 303, 304, 305.

The central magnet block 330 typically has a length of 600 cm (along x), a width of 644 cm (along y) and a depth of 240 cm (along z). The magnet block 330 also has five recesses each corresponding to one of the chambers 301, 302, 303, 304, 305. These recesses typically have a width of 104 cm or 98 cm (along y) and a length of 600 cm (along x), which makes it possible to have a magnet block 330 with openings in the upper part and in the lower part to facilitate the extraction of oxygen trapped by the cryo-panels.

The dimensions, along the y axis, of the chambers 301, 302, 303, 304, 305 are advantageously different and are alternated so as to produce magnetic fields leading to the production of a significant electron cyclotron resonance volume.

The central magnet block 330 typically represents part of the magnetic structure of the device 300 making it possible to surround each chamber 301, 302, 303, 304, 305 by bar magnets, the bar magnets being located at the minimum (Bₘᵢₙ) of the profiles of the module of the magnetic field present in each chamber.

Moreover, the central magnet block 330 makes it possible to reduce the number of bar magnets surrounding each plasma chamber by proposing a single magnetic structure by replacing the plurality of separate bar magnets, as shown with reference to FIG. 6. This single structure also makes it possible to ensure a value of the module of the magnetic field which is close to the value of the resonance magnetic field extended over a large length of each plasma chamber.

FIG. 9 is a variant of the hydrogen production device illustrated in FIGS. 6, 7 and 8 (the common means between the devices 100, 200 and 300 bearing the same reference numerals and performing the same functions).

In accordance with this fourth embodiment, the device 400 differs from the device 100 of FIG. 6 in that it comprises a hydrogen-oxygen separation system 420 formed by;
a first hydrogen-permeable membrane 421 forming the outer lateral walls of the first chamber 401 and making it possible to trap oxygen inside the chamber 401 and to recover hydrogen in an enclosure at the periphery of the first chamber 401;
a second hydrogen-permeable membrane 422 forming the outer lateral walls of the first chamber 402 and making it possible to trap oxygen inside the chamber 402 and to recover hydrogen in an enclosure at the periphery of the first chamber 401;
pumps 424 making it possible to recover the hydrogen in gaseous form in the enclosures at the periphery of the chambers 401, 402;
pumps 425 making it possible to recover the oxygen in gaseous form in the chambers 401, 402.

The permeable separation membranes 421, 422 may also be formed by a metal membrane (such as a palladium membrane), a chemical membrane which absorbs oxygen, or else a magnetic membrane which traps oxygen by paramagnetism.

FIG. 10 is a simplified view of a surface-treatment device 500 comprising a device 600 for generating electron cyclotron resonance plasma according to the invention, as described and illustrated in FIGS. 2, 3, 4 and 5.

The surface-treatment device 500 comprises, unless otherwise indicated, all the features of a plasma generation device 600 described above.

The device 500 comprises a plurality of chambers, of which two chambers are denoted by reference numerals 501 and 502.

The two chambers 501, 502 communicate, at their end opposite the injector 18, by means of a chamber 521 in which a substrate able to receive the different dissociation products of the chambers is displaced, the nature of the dissociation products being a function of the nature of the plasmas generated in each chamber.

By way of example, the device 500 may be used for an application of hardening of an aluminium substrate by implantation of nitrogen ion at the surface. For this, the device 500 for example has seven chambers each comprising a plasma making is possible to provide different nitrogen ions. The aluminium substrate moving in front of each chamber will first receive N⁺ ions when passing from the first plasma, then N²⁺ ions when passing from the second plasma, up to N⁷⁺ ions when passing from the seventh plasma. The assembly being brought to a fixed high voltage, the energy of the ions is thus proportional to the charge of the ion, and different penetration depths of the nitrogen atoms in the aluminium will be obtained.

The device 500 is thus a compact device which may comprise adjacent plasmas of the same nature or of different nature for the surface treatment of a sample.

The sample to be treated passes successively in front of the different plasmas, for example passing from the stripping of the argon then to the deposition of the catalyst so as to finish with the implantation of the desired element (for example carbon).

For example, in an application intended for the growth of carbon nanotubes, the substrate passes successively in front of four plasmas so to as to undergo the different phases of production of carbon nanotubes: stripping, deposition of silicon, deposition of the catalyst, growth of nanotubes.

The invention thus proposes a compact device for generating electron cyclotron resonance plasma and having a plurality of plasmas, the plasmas possibly being identical, for example for high-volume production of hydrogen, or different, for example for surface treatment.

The invention has primarily been described for an application enabling extraction of the hydrogen, in gaseous form, located at the end of the chambers and pumping the hydrogen axially; however, it is also possible to equip the device, in the case of an application of hydrogen production, with a hydrogen extraction means which pump the hydrogen from the chamber radially at the end of each chamber. In fact, in the case of use of a single magnetic mirror configuration, as shown in FIGS. 2 to 6, there may be a considerable flow of particles in the axis of the machine, this flow of particles being less, the greater is Bₘₐₓ. A radial pumping of the hydrogen makes it possible to obtain 100% pure hydrogen.

The invention has primarily been described, in the embodiments illustrated with reference to FIGS. 6 and 7, with an extraction of hydrogen at the end of the chambers, caused by aspiration of the hydrogen in gaseous form by means of a pump. In accordance with the invention, it is also possible to introduce into each chamber, at the zone of hydrogen extraction and outside the magnetic field lines, cold-wall cryogenic condensers for trapping the hydrogen, such as cryo-panels, either solid or with apertures, and of which the temperature of the walls is less than 5K. The hydrogen and oxygen are thus fixed independently on the cold walls, such that it is suffice to re-heat them independently of one another to recover the hydrogen and oxygen separately either in liquid form or in gaseous form.

The invention has primarily been described with a plurality of microwave generators injecting high-frequency waves via a plurality of propagation means in each plasma chamber; however, it is also possible according to the invention to only use a single microwave generator for the entire device comprising a plurality of plasma chambers by using a multi-guide high-frequency injection device possibly with high-frequency cones.

The invention has primarily been described with a plurality of means for injecting water vapours; however, it is also possible in accordance with the invention to provide a single means for injecting water vapours having a main entry into the device and a system for distributing vapour towards each chamber and each plasma volume.

The invention has primarily been described with a magnetic configuration comprising a minimum-B substantially equal to or less than the value corresponding to the resonance magnetic field, of which the value of the minimum-B is a value which is constant over a specific length of the chamber of the device corresponding to the distance between the two maxima (Bₘₐₓ); however, in another representation of the invention, the minimum-B of the magnetic configuration may fluctuate around a minimum value, whilst remaining very close to said minimum value over a large distance of the chamber of the device corresponding to the distance between the two maxima (Bₘₐₓ).

Lastly, the invention has primarily been described with an axial magnetic field; however, it is also possible to add a radial component to the axial magnetic field, for the dissociation for example of other elements requiring the use of a radial magnetic field and/or to avoid radial leaks of the plasmas caused by the drift of the particles and to thus ensure an improved confinement of the plasmas.

Of course, the invention is not limited to the embodiments which have just been described.

Thus, if it is desired to treat a greater number of molecules to be dissociated, it is possible to increase the dimensions of the assembly whilst ensuring that there are resonance zones in each plasma chamber. Thus, it is possible in accordance with requirements to increase the length or volume of the minimum-B, which is equal to or slightly less than the resonance, up to several metres or several m³. It will be noted that the longer the volume of the minimum-B, the more effective the device according to the invention.

Although the invention has been more specifically described for low-frequency microwave frequencies of approximately 2.45 GHz, it is of course also possible to use higher microwave frequencies, as well as two injections of microwaves with similar frequencies so as to obtain a minimum-B value between the two resonance values, as well as a plurality of injections of microwaves of which the bandwidth of each (several MHz) leads to a very wide frequency bandwidth and thus to a larger resonance zone.

In particular, the other advantages of the invention are as follows:
no CO2 emission;
no use of electrodes, no ohmic heating and no elevated temperatures.

1. A device (600) for generating electron cyclotron resonance plasma, the device comprising:
at least two sealed adjacent chambers under vacuum configured to contain plasmas;
a high-frequency wave injector inside said at least two sealed chambers;
a magnetic structure configured to generate a magnetic field in said at least two adjacent chambers comprising a plurality of parallepipedal permanent magnets and generating at least two plasmas along the magnetic field lines, a module of said magnetic field having a magnetic mirror configuration with at least one plasma electron cyclotron resonance zone for each plasma, said magnetic structure comprising at least one permanent magnet contributing to the formation of a plasma in each of said at least two chambers, such that said at least two chambers share the same at least one permanent magnet on their common wall,
said magnetic mirror configuration being such that the module of said magnetic field has a substantially constant non-point minimum substantially equal to a magnetic field corresponding to the electron cyclotron resonance, extended at least in part along a first longitudinal axis of said at least two chambers and at least in part along a second axis perpendicular to said first longitudinal axis and parallel to the surface of said permanent magnets such that said at least two chambers have a volume of electron cyclotron resonance plasma.

2. The device for generating electron cyclotron resonance plasma according to claim 1, wherein said plurality of permanent magnets form an open magnetic structure.

3. The device for generating electron cyclotron resonance plasma according to claim 1, wherein said permanent magnets have the same direction of magnetisation and/or are of different sizes.

4. The device for generating electron cyclotron resonance plasma according to claim 1, wherein said plurality of permanent magnets comprises at least two magnets defining the ends of each chamber and generating a mirror magnetic field, said at least two magnets being located on either side of at least one magnet generating a resonance zone.

5. The device for generating electron cyclotron resonance plasma according to claim 1, wherein said at least two sealed chambers communicate at one of their ends.

6. The device for generating electron cyclotron resonance plasma according to claim 1, wherein said high-frequency wave injector is a multi-guide wave injector coupled to a single high-frequency generator.

7. The device for generating electron cyclotron resonance plasma according to claim 1, wherein said high-frequency wave injector is a waveguide injector comprising a cone for the distribution of microwaves in said plurality of chambers, said high-frequency wave injector being coupled to a single high-frequency generator.

8. The device for generating electron cyclotron resonance plasma according to claim 1, comprising a multi-frequency high-frequency wave injector.

9. A device for hydrogen production using an electron cyclotron resonance plasma, comprising:
a plasma generation device according to claim 1;
a water vapour injector into said at least two chambers, the electrons of said plasmas dissociating, at least in part, the water molecules introduced in the vapour phase and ionising, at least in part, the dissociation products, said water vapour injector injecting said vapour in such a way that it said vapour is directed along said longitudinal axis of said at least two chambers;
a hydrogen and oxygen separator;
a recovering device for recovering configured to recover the hydrogen produced by the dissociation.

10. The hydrogen production device according to claim 9, comprising a recovering device configured to recover undissociated water, said recovering device being formed by a condenser and/or being located substantially along the axis of injection of the water vapour.

11. The hydrogen production device according to claim 9, comprising at least one system for re-injecting the undissociated water in vapour phase produced by said recovering device for recovering undissociated water.

12. The hydrogen production device according to claim 9, wherein said recovering device comprises a pump for pumping the hydrogen in gaseous phase and/or at least one cryogenic condenser for freezing the hydrogen.

13. The hydrogen production device according to claim 9, wherein said water vapour injector is configured to inject said vapour in the form of a supersonic jet, said water vapour injector comprising a flat nozzle and a divertor, said divertor being used to shape said vapour jet so that said vapour jet is directed along the longitudinal axis of said at least two chambers.

14. The hydrogen production device according to claim 9, wherein said hydrogen and oxygen separator is formed by at least one selective cryogenic condenser configured to freeze the oxygen produced by the dissociation without freezing the hydrogen produced by the dissociation, said at least one selective cryogenic condenser freezing the oxygen along said volume of plasma generated in said at least two chambers.

15. The hydrogen production device according to claim 14, wherein said at least one selective cryogenic condenser for freezing the oxygen forms the inner wall of said chamber and/or is located at said magnetic field non-point minimum.

16. The hydrogen production device according to claim 9, comprising a second cryogenic condenser configured to freeze the oxygen produced by the dissociation, said condenser being located at the end of said at least two chambers between said magnetic mirror configuration and said hydrogen recovery device.

17. The hydrogen production device according to claim 9, wherein said hydrogen and oxygen separator is formed by a hydrogen-permeable membrane, said permeable membrane separating the hydrogen produced by the dissociation along said volume of plasma generated in said at least two chambers.

18. A device for producing thin layers, comprising:
a plasma generation device according to claim 1;
a plasma component injector into said at least two chambers, the electrons of said plasmas dissociating, at least in part, the molecules of said introduced component and ionising, at least in part, the products of the dissociation, said injector injecting said component in such a way that it said component is directed along said longitudinal axis of said at least two chambers;
said plasmas successively producing thin layers of product of the dissociation of said component so as to form a stack of thin layers on a substrate.

19. The device according to claim 18, comprising a system configured to displace said substrate by positioning said substrate successively in front of each plasma.

20. The device according to claim 18, wherein said component injected into each of said at least two chambers is different in nature so as to form a stack of thin layers of different natures on said substrate.

21. An implantation device, comprising:
a plasma generation device according to claim 1;
a plasma component injector into said at least two chambers, the electrons of said plasmas dissociating the molecules of said introduced component and ionising the products of the dissociation, said injector injecting said component in such a way that said component is directed along said longitudinal axis of said at least two chambers;
a high voltage of single polarisation for extracting the ions produced by each plasma and implanting them in the material;
said plasmas each having a different state of charge distribution making it possible to successively implant ions of the same nature and/or having different charges.
